(19) United States
(12) Patent Application Publication
(10) Pub. No.: US 2023/0129417 A1
(43) Pub. Date: Apr. 27, 2023

(54) PICKUP APPARATUS AND PICKUP METHOD OF SEMICONDUCTOR DIE

(71) Applicant: SHINKAWA LTD., Tokyo (JP)

(72) Inventors: Toru MAEDA, Tokyo (JP); Hiroshi OMATA, Tokyo (JP)

(73) Assignee: SHINKAWA LTD., Tokyo (JP)

(21) Appl. No.: 17/908,541

(22) PCT Filed: Feb. 17, 2021
(86) PCT No.: PCT/JP2021/005985

§ 371 Date: Sep. 1, 2022

(51) Int. Cl. H01L 21/67; H01L 21/683

(52) U.S. Cl. CPC H01L 21/67132; H01L 21/6838; H01L 21/6836; H01L 2221/6839

(57) ABSTRACT

In a pickup apparatus of a semiconductor die, a suction surface sucking a wafer sheet is a curved surface which is curved convexly upward, and after raising a stage to push up the wafer sheet, a control part creates a vacuum inside the stage to suck the wafer sheet to the suction surface, and after sucking the wafer sheet to the suction surface, the control part protrudes a moving element from the suction surface, and picks up a semiconductor die from the wafer sheet by a collet.

### TECHNICAL FIELD

The present invention relates to a structure of a pickup apparatus of a semiconductor die and a pickup method of a semiconductor die for picking up a semiconductor die from a wafer sheet.

### RELATED ART

A semiconductor die is manufactured by cutting a wafer having a size of 6 inches or 8 inches into a predetermined size. At the time of cutting, a wafer sheet is attached to the back surface so that the cut semiconductor dies do not fall apart, and the wafer is cut from the front surface side by a dicing saw or the like. At this time, the wafer sheet attached to the back surface is slightly cut but is not cut apart to hold each semiconductor die. Then, each of the cut semiconductor dies is picked up from the wafer sheet one by one and sent to a next process such as die bonding.

The following method has been proposed as a method for picking up a semiconductor die from a wafer sheet: the wafer sheet is pushed up by a stage having a spherical suction surface, and the wafer sheet is vacuum-sucked to the suction surface, a push-up pin arranged inside the stage pushes up the wafer sheet to penetrate therethrough, the semiconductor die attached to the upper surface of the wafer sheet is pushed up from below, and the semiconductor die is picked up by a collet (see, for example, Patent Document 1).

### CITATION LIST

### Patent Document

[Patent Document 1] Japanese Patent Application Laid-Open No. H10-92907

### SUMMARY OF INVENTION

### Problem to be Solved by Invention

According to the method of Patent Document 1, on the spherical suction surface of the stage, since a gap between side surfaces of adjacent semiconductor dies increases toward the upper side, the adjacent semiconductors do not come into contact with each other and cracking or chipping does not occur. However, as shown in FIG. 1 of Patent Document 1, at the peripheral edge of the stage, the wafer sheet is deformed convexly downward, and the gap between the side surfaces of the adjacent semiconductor dies becomes smaller toward the upper side.

On the other hand, in recent years, the semiconductor die is often cut by a laser. In this case, the cutting width of the semiconductor die becomes very narrow, and the gap between the side surfaces of the adjacent semiconductor dies also becomes very narrow. For this reason, when the wafer sheet is deformed convexly downward at the peripheral edge of the stage and the gap between the side surfaces of the adjacent semiconductor dies becomes smaller toward the upper side, the side surfaces of the adjacent semiconductor dies may come into contact with each other, thus causing cracking or chipping.

Therefore, a pickup apparatus of a semiconductor die of the present invention aims to suppress damage to a semiconductor die when the semiconductor die is picked up from a wafer sheet.

### Means for Solving Problem

A pickup apparatus of a semiconductor die of the present invention is a pickup apparatus of a semiconductor die which picks up a semiconductor die attached to an upper surface of a wafer sheet. The pickup apparatus of a semiconductor die includes a stage, a stage drive mechanism, and a moving element. The stage includes a suction surface sucking a lower surface of the wafer sheet and an opening provided in the suction surface. The stage drive mechanism drives the stage in an up-down direction. The moving element is arranged in the opening of the stage and moves so that a tip of the moving element protrudes from the suction surface. The pickup apparatus of a semiconductor die includes a moving element drive mechanism, a collet, a vacuum device, and a control part. The moving element drive mechanism drives the moving element in the up-down direction. The collet picks up the semiconductor die. The vacuum device creates a vacuum inside the stage. The control part adjusts operations of the stage drive mechanism, the moving element drive mechanism, the collet, and the vacuum device. The suction surface is a curved surface which is curved convexly upward. The control part raises, by the stage drive mechanism, the stage to push up the wafer sheet. After pushing up the wafer sheet, the control part creates, by the vacuum device, a vacuum inside the stage to suck the wafer sheet to the suction surface. After sucking the wafer sheet to the suction surface, the control part protrudes, by the moving element drive mechanism, the moving element from the suction surface to push up the semiconductor die to be picked up from under the wafer sheet, and picks up, by the collet, the semiconductor die from the wafer sheet.

In this manner, by configuring the suction surface of the stage as a curved surface which is curved convexly upward, on the suction surface of the stage, the gap between the side surfaces of the adjacent semiconductor dies increases toward the upper side, and it is possible to prevent the adjacent semiconductors from coming into contact with each other and thus causing cracking or chipping. Further, since the wafer sheet is sucked to the suction surface after pushing up the wafer sheet by the stage, when sucking the wafer sheet to the suction surface, the wafer sheet is not deformed convexly downward at the peripheral edge of the stage, and the gap between the side surfaces of the adjacent semiconductor dies does not become smaller toward the upper side. Therefore, it is possible to prevent the side surfaces of adjacent semiconductor dies from coming into contact with each other at the peripheral edge of the stage and thus causing cracking and chipping.

In the pickup apparatus of a semiconductor die of the present invention, the stage may have a cylindrical shape, and the suction surface may be a spherical cap surface. When pushing up the wafer sheet, the control part may raise the stage until the lower surface of the wafer sheet is in contact with a corner part between a side surface in a cylindrical shape of the stage and the suction surface.

In this manner, since the stage is raised until the lower surface of the wafer sheet is in contact with the corner part between the side surface in a cylindrical shape of the stage and the suction surface, the wafer sheet at the peripheral edge of the stage is deformed to be convex upward, and since the gap between the side surfaces of the adjacent semiconductor dies increases toward the upper side, it is possible to prevent the adjacent semiconductors from coming into contact with each other and thus causing cracking or chipping.

In the pickup apparatus of a semiconductor die of the present invention, the corner part may be composed of a curved surface connecting the side surface of the stage and the suction surface. When pushing up the wafer sheet, the control part may raise the stage until a height of a ridge line between the side surface of the stage and the suction surface at the corner part is equal to or greater than a height of the lower surface of the wafer sheet at the side surface of the stage.

In this manner, since the stage is raised until the height of the ridge line between the side surface of the stage and the suction surface at the corner part is equal to or greater than the height of the lower surface of the wafer sheet at the side surface of the stage, the wafer sheet at the peripheral edge of the stage is deformed to be convex upward, and since the gap between the side surfaces of the adjacent semiconductor dies increases toward the upper side, it is possible to prevent the adjacent semiconductors from coming into contact with each other and thus causing cracking or chipping.

In the pickup apparatus of a semiconductor die of the present invention, the stage may have a cylindrical shape, the suction surface may be a spherical cap surface, the opening of the stage may be arranged at a center of the suction surface, and the suction surface may be composed of an inner peripheral part around the opening and an outer peripheral part on an outer side of the inner peripheral part, and include, in the inner peripheral part, an inner suction hole communicating with the vacuum device. When pushing up the wafer sheet, the control part may raise the stage until the lower surface of the wafer sheet is in contact with an outer peripheral end of the inner peripheral part of the stage. When sucking the wafer sheet, the control part may create, by the vacuum device, a vacuum at the inner suction hole to suck the wafer sheet to the inner peripheral part of the suction surface.

In this manner, since the wafer sheet is sucked to the inner peripheral part after the stage is raised until the outer peripheral end of the inner peripheral part of the suction surface, which is a spherical cap surface, is in contact with the lower surface of the wafer sheet, when the wafer sheet is sucked to the inner peripheral part of the suction surface, it is possible to prevent the wafer sheet from being deformed convexly downward at the outer peripheral part of the suction surface, and prevent the adjacent semiconductor dies from coming into contact with each other and thus causing cracking or chipping.

In the pickup apparatus of a semiconductor die of the present invention, the stage may further include, in the outer peripheral part, an outer suction hole communicating with the vacuum device. When pushing up the wafer sheet, the control part may raise the stage until the lower surface of the wafer sheet is in contact with an outer peripheral end of the outer peripheral part of the stage. When sucking the wafer sheet, the control part may create, by the vacuum device, a vacuum at the inner suction hole and the outer suction hole to suck the wafer sheet to the inner peripheral part and the outer peripheral part of the suction surface.

In this manner, since the wafer sheet is in close contact with the inner peripheral part and the outer peripheral part of the suction surface of the stage, when the wafer sheet is sucked to the inner peripheral part and the outer peripheral part of the suction surface, it is possible to prevent the wafer sheet from being deformed convexly downward at the outer peripheral part of the suction surface, and prevent the adjacent semiconductor dies from coming into contact with each other and thus causing cracking or chipping.

In the pickup apparatus of a semiconductor die of the present invention, in a case of picking up a semiconductor die attached to the upper surface of a peripheral portion of the wafer sheet, when pushing up the wafer sheet, the control part may raise the stage until the lower surface of the wafer sheet is in contact with the outer peripheral end of the inner peripheral part of the stage, and when sucking the wafer sheet, the control part may create, by the vacuum device, a vacuum at the inner suction hole to suck the wafer sheet to the inner peripheral part of the suction surface. In a case of picking up a semiconductor die attached to the upper surface of a central portion of the wafer sheet, when pushing up the wafer sheet, the control part may raise the stage until the lower surface of the wafer sheet is in contact with the outer peripheral end of the outer peripheral part of the stage, and when sucking the wafer sheet, the control part may create, by the vacuum device, a vacuum at the inner suction hole and the outer suction hole to suck the wafer sheet to the inner peripheral part and the outer peripheral part of the suction surface.

Accordingly, in the case of picking up a semiconductor die attached to the peripheral portion of the wafer sheet, it is possible to suppress occurrence of chipping or cracking in the semiconductor dies located at the peripheral edge of the stage.

In the pickup apparatus of a semiconductor die of the present invention, the moving element may be composed of: a first push-up pin arranged at a center of the stage; and a second push-up pin in a cylindrical shape arranged on an outer circumference of the first push-up pin. The moving element drive mechanism may drive the first push-up pin and the second push-up pin in the up-down direction. When picking up the semiconductor die, after protruding, by the moving element drive mechanism, the second push-up pin from the suction surface, the control part may protrude the first push-up pin to a position higher than a tip of the second push-up pin.

In this manner, after the second push-up pin in a cylindrical shape is raised and a lead for peeling is created on the wafer sheet at an outer peripheral part of the semiconductor die, since the semiconductor die is further pushed up by the first push-up pin and picked up from the wafer sheet, it is possible to pick up the semiconductor die from the wafer sheet without damage.

A pickup method of a semiconductor die of the present invention is a pickup method of a semiconductor die which picks up a semiconductor die attached to an upper surface of a wafer sheet. The pickup method of a semiconductor die includes the following processes. In a preparation process, a pickup apparatus is prepared, the pickup apparatus including: a stage which includes a suction surface sucking a lower surface of the wafer sheet and an opening provided in the suction surface; a moving element which is arranged in the opening of the stage and moves so that a tip of the moving element protrudes from the suction surface; and a collet which picks up the semiconductor die. The suction surface is a curved surface which is curved convexly upward. In a push-up process, the stage is raised to push up the wafer sheet. In a suction process, the wafer sheet is sucked to the suction surface after the push-up process. In a pickup process, after the suction process, the moving element is protruded from the suction surface to push up the semiconductor die to be picked up from under the wafer sheet, and the semiconductor die is picked up by the collet.

In the pickup method of a semiconductor die of the present invention, in the pickup apparatus of a semiconductor die prepared in the preparation process, the stage may have a cylindrical shape, and the suction surface may be a spherical cap surface. In the push-up process, the stage may be raised until the lower surface of the wafer sheet is in contact with a corner part between a side surface in a cylindrical shape of the stage and the suction surface.

In the pickup method of a semiconductor die of the present invention, in the pickup apparatus of a semiconductor die prepared in the preparation process, the corner part may be composed of a curved surface connecting the side surface of the stage and the suction surface. In the push-up process, the stage may be raised until a height of a ridge line between the side surface of the stage and the suction surface at the corner part is equal to or greater than a height of the lower surface of the wafer sheet at the side surface of the stage.

In the pickup method of a semiconductor die of the present invention, in the pickup apparatus of a semiconductor die prepared in the preparation process, the stage may have a cylindrical shape, the suction surface may be a spherical cap surface, the opening of the stage may be arranged at a center of the suction surface, and the suction surface may be composed of an inner peripheral part around the opening and an outer peripheral part on an outer side of the inner peripheral part, and include an inner suction hole in the inner peripheral part. In the push-up process, the stage may be raised until the lower surface of the wafer sheet is in contact with an outer peripheral end of the inner peripheral part of the stage. In the suction process, a vacuum may be created at the inner suction hole to suck the wafer sheet to the inner peripheral part of the suction surface.

In the pickup method of a semiconductor die of the present invention, the pickup apparatus of a semiconductor die prepared in the preparation process may further include an outer suction hole in the outer peripheral part. In the push-up process, the stage may be raised until the lower surface of the wafer sheet is in contact with an outer peripheral end of the outer peripheral part of the stage. In the suction process, a vacuum may be created at the inner suction hole and the outer suction hole to suck the wafer sheet to the inner peripheral part and the outer peripheral part of the suction surface.

In the pickup method of a semiconductor die of the present invention, in a case of picking up a semiconductor die attached to the upper surface of a peripheral portion of the wafer sheet, in the push-up process, the stage may be raised until the lower surface of the wafer sheet is in contact with the outer peripheral end of the inner peripheral part of the stage, and in the suction process, a vacuum may be created at the inner suction hole to suck the wafer sheet to the inner peripheral part of the suction surface. In a case of picking up a semiconductor die attached to the upper surface of a central portion of the wafer sheet, in the push-up process, the stage may be raised until the lower surface of the wafer sheet is in contact with the outer peripheral end of the outer peripheral part of the stage, and in the suction process, a vacuum may be created at the inner suction hole and the outer suction hole to suck the wafer sheet to the inner peripheral part and the outer peripheral part of the suction surface.

In the pickup method of a semiconductor die of the present invention, in the pickup apparatus of a semiconductor die prepared in the preparation process, the moving element may be composed of a first push-up pin arranged at a center of the stage and a second push-up pin in a cylindrical shape arranged on an outer circumference of the first push-up pin. In the pickup process, after the second push-up pin is protruded from the suction surface, the first push-up pin may be protruded to a position higher than a tip of the second push-up pin, and the semiconductor die may be picked up by the collet.

### Effects of Invention

The pickup apparatus of a semiconductor die of the present invention can suppress damage to a semiconductor die when the semiconductor die is picked up from a wafer sheet.

### BRIEF DESCRIPTION OF DRAWINGS

FIG. 1 is a system view showing a configuration of a pickup apparatus of a semiconductor die according to an embodiment.

FIG. 2 is a cross-sectional view of a stage of the pickup apparatus of a semiconductor die shown in FIG. 1.

FIG. 3 is a detailed cross-sectional view of part A shown in FIG. 2.

FIG. 4 is a view illustrating a contact region between a lower surface of a wafer sheet and a suction surface of the stage when changing a height of the stage.

FIG. 5 is a view illustrating a pickup operation of a semiconductor die by the pickup apparatus of a semiconductor die shown in FIG. 1, and is cross-sectional view showing the stage, the wafer sheet, and the semiconductor die when the stage is raised to a position (Z=0) at which an apex of the stage is in contact with the lower surface of the wafer sheet.

FIG. 6 is a cross-sectional view showing the stage, the wafer sheet, and the semiconductor die when the apex of the stage is raised from the state shown in FIG. 5 to Z1 shown in FIG. 4.

FIG. 7 is a cross-sectional view showing the stage, the wafer sheet, and the semiconductor die when the apex of the stage is raised from the state shown in FIG. 6 to Z3 shown in FIG. 4.

FIG. 8 is a detailed cross-sectional view of part B shown in FIG. 7.

FIG. 9 is a cross-sectional view showing the stage, the wafer sheet, and the semiconductor die when a vacuum is created inside the stage from the state shown in FIG. 7 to suck the wafer sheet to the suction surface of the stage.

FIG. 10 is a cross-sectional view showing the stage, the wafer sheet, the semiconductor die, and a collet when a second push-up pin is protruded from the suction surface from the state shown in FIG. 9.

FIG. 11 is a cross-sectional view showing the stage, the wafer sheet, the semiconductor die, and the collet when a tip of a first push-up pin is raised higher than a tip of the second push-up pin from the state shown in FIG. 10 to push up the semiconductor die.

FIG. 12 is a view illustrating a positional relationship and dimensions between the stage and the wafer sheet when the stage is raised to a height Z2.

FIG. 13 is a view showing a cross section of a stage and a system of a vacuum device connected to the stage of a pickup apparatus of a semiconductor die of another embodiment.

FIG. 14 is a view illustrating a first pickup operation of a semiconductor die by the pickup apparatus of a semiconductor die shown in FIG. 13, and is a cross-sectional view showing the stage, the wafer sheet, and the semiconductor die when the apex of the stage is raised to Z1 shown in FIG. 4.

FIG. 15 is a cross-sectional view showing a state in which a vacuum is created at an inner suction hole to suck the wafer sheet to an inner peripheral part of the suction surface from the state shown in FIG. 14.

FIG. 16 is a cross-sectional view showing the stage, the wafer sheet, the semiconductor die, and the collet when the second push-up pin is protruded from the suction surface from the state shown in FIG. 15.

FIG. 17 is a cross-sectional view showing the stage, the wafer sheet, the semiconductor die, and the collet when the tip of the first push-up pin is raised higher than the tip of the second push-up pin from the state shown in FIG. 16 to push up the semiconductor die.

FIG. 18 is a view illustrating a second pickup operation of a semiconductor die by the pickup apparatus of a semiconductor die shown in FIG. 13, and is a cross-sectional view showing the stage, the wafer sheet, and the semiconductor die when the apex of the stage is raised to Z2 shown in FIG. 4.

FIG. 19 is a cross-sectional view showing the wafer sheet, the semiconductor die, and the collet in a state in which a vacuum is created at an inner suction hole and an outer suction hole from the state shown in FIG. 18 to suck the wafer sheet to an inner peripheral part and an outer peripheral part of the suction surface.

FIG. 20 is a view illustrating a positional relationship and dimensions between the stage and the wafer sheet when the stage is raised to a height Z4 in a case where the stage is deviated to one side from the center of a wafer ring.

FIG. 21 is a cross-sectional view showing the stage, the wafer sheet, and the semiconductor die when a vacuum is created inside the stage to suck the lower surface of the wafer sheet to the suction surface, in a state in which the height Z of the stage before raising the stage is 0 shown in FIG. 4, in a pickup apparatus of a semiconductor die of a comparative example.

### DESCRIPTION OF EMBODIMENTS

Hereinafter, a pickup apparatus 100 of a semiconductor die of an embodiment will be described with reference to the drawings.

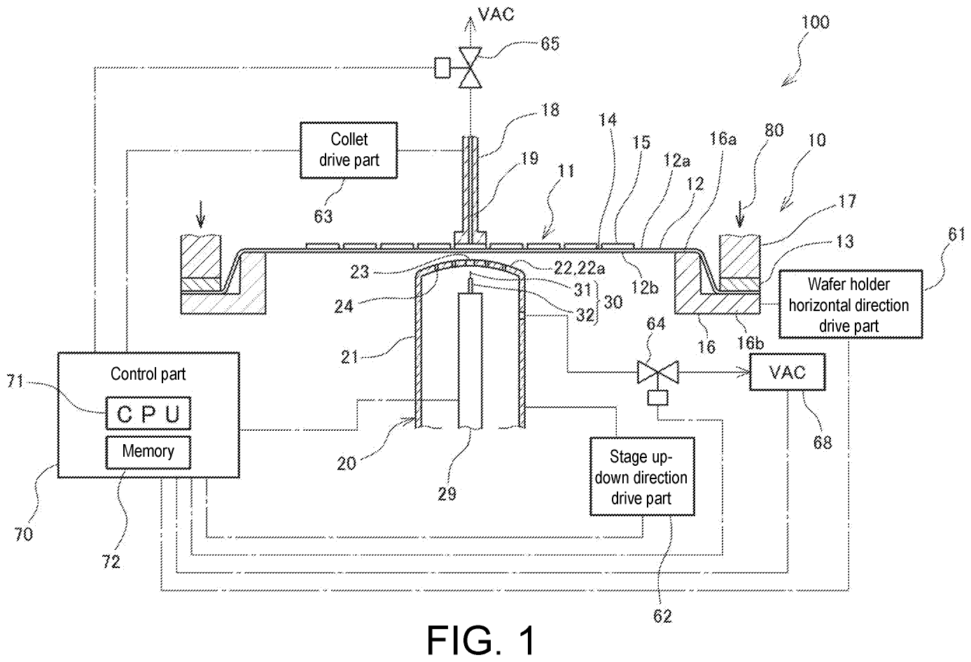

As shown in FIG. 1, the pickup apparatus 100 of a semiconductor die (hereinafter referred to as a pickup apparatus 100) of the embodiment includes a wafer holder 10, a stage 20, a collet 18, a wafer holder horizontal direction drive part 61, a stage up-down direction drive part 62, a collet drive part 63, vacuum valves 64 and 65, a vacuum device 68, and a control part 70.

The wafer holder 10 includes an annular expanding ring 16 having a flange part and a ring retainer 17, and holds a wafer sheet 12 to which a semiconductor die 15 obtained by cutting a wafer 11 is attached on an upper surface 12a. The wafer holder 10 is moved in the horizontal direction by the wafer holder horizontal direction drive part 61.

Herein, the wafer sheet 12 to which the semiconductor die 15 is attached on the upper surface 12a is held by the wafer holder 10 in the following manner. The wafer sheet 12 is attached to a back surface of the wafer 11, and a metal ring 13 is attached to an outer peripheral part of the wafer sheet 12. The wafer 11 is cut from a front surface side by a dicing saw or the like in a cutting process into each semiconductor die 15, and a gap 14 is formed between the semiconductor dies 15 during dicing. Even though the wafer 11 is cut apart, the wafer sheet 12 is not cut apart, and each semiconductor die 15 is held by the wafer sheet 12.

A lower surface 12b of the wafer sheet 12 to which the semiconductor die 15 is attached on the upper surface 12a is placed to be in contact with a holding surface 16a of the expanding ring 16, and is adjusted so that a position of the ring 13 is above a flange 16b of the expanding ring 16. Then, as shown by an arrow 80 in FIG. 1, the ring 13 is pressed on the flange 16b of the expanding ring 16 from above by the ring retainer 17 and fixed on the flange 16b. Accordingly, the wafer sheet 12 to which the semiconductor die 15 is attached on the upper surface 12a is held by the wafer holder 10. At this time, the lower surface 12b of the wafer sheet 12 is fixed to an outer peripheral end of the holding surface 16a of the expanding ring 16.

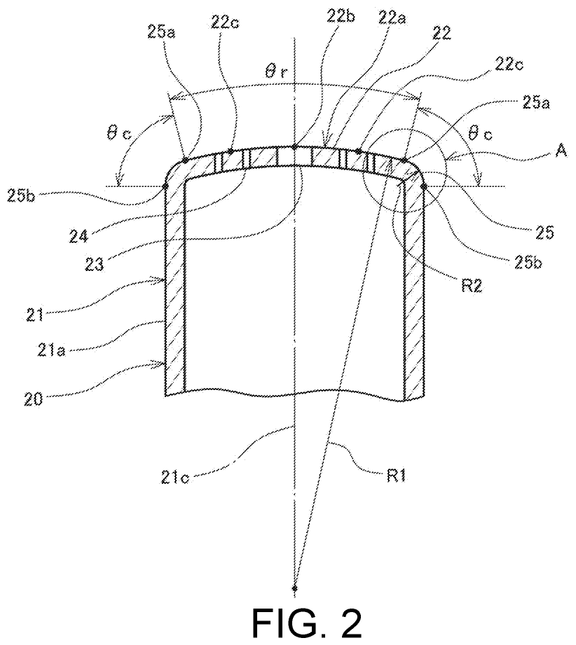

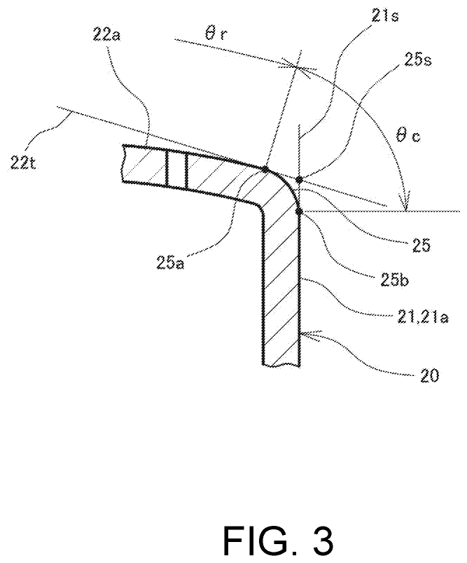

The stage 20 is arranged on a lower surface of the wafer holder 10. The stage 20 is composed of a cylindrical part 21 having a cylindrical shape and an upper end plate 22 which is an upper lid of the cylindrical part 21. The surface of the upper end plate 22 is a suction surface 22a which sucks the lower surface 12b of the wafer sheet 12; an opening 23 through which a moving element 30 enters and exits is provided at a center of the upper end plate 22, and a suction hole 24 for sucking the lower surface 12b of the wafer sheet 12 is provided around the opening 23. The moving element 30 and a moving element drive mechanism 29 which drives the moving element 30 are provided inside the cylindrical part 21. The moving element 30 is composed of a first push-up pin 31 arranged at a center of the stage 20 and a cylindrical second push-up pin 32 arranged on an outer circumference of the first push-up pin 31. The moving element drive mechanism 29 includes therein a drive motor, a gear, a link mechanism, etc. and drives the first push-up pin 31 and the second push-up pin 32 in the up-down direction to protrude from the suction surface 22a through the opening 23. The entirety of the stage 20 is moved in the up-down direction by the stage up-down direction drive part 62. Further, the inside of the stage 20 is connected to the vacuum device 68 via the vacuum valve 64. The details of the stage 20 will be described with reference to FIG. 2 and FIG. 3.

The collet 18 is arranged on the upper side of the wafer sheet 12 to suck and hold the semiconductor die 15 on a lower surface, and picks up the semiconductor die 15 from the upper surface 12a of the wafer sheet 12. The collet 18 is provided with a suction hole 19 for vacuum-sucking the semiconductor die 15 on the lower surface. The suction hole 19 is connected to the vacuum device 68 via the vacuum valve 65. The collet 18 is moved in the up-down and left-right directions by the collet drive part 63.

The wafer holder horizontal direction drive part 61, the stage up-down direction drive part 62, the collet drive part 63, the vacuum valves 64 and 65, the vacuum device 68, and the moving element drive mechanism 29 are connected to the control part 70 and operate according to commands of the control part 70. The control part 70 is a computer including a CPU 71 which is a processor processing information internally and a memory 72 storing programs and the like.

Next, the configuration of the stage 20 will be described with reference to FIG. 2 and FIG. 3. As described above, the stage 20 is composed of the cylindrical part 21 and the upper end plate 22 which is an upper lid of the cylindrical part 21. The surface of the upper end plate 22 is a curved surface which is curved convexly upward, and forms the suction surface 22a which sucks the lower surface 12b of the wafer sheet 12. As shown in FIG. 2, the suction surface 22a is a spherical cap surface having a radius R1 and a central angle being θr. The suction surface 22a and a side surface 21a of the cylindrical part 21 are connected by a curved surface. The curved surface is an annular surface of an arc cross section having a radius R2 and an angle θc, and forms a corner part 25 connecting the suction surface 22a and the side surface 21a. Herein, the radius R2 is smaller than the radius R1, and is, for example, about 0.1 to 0.5 mm with respect to about R=600 mm.

An outer peripheral end of the suction surface 22a and an inner peripheral end of the corner part 25 are connected by an annular connecting line 25a so that a tangential direction of the outer peripheral end of the suction surface 22a becomes a tangential direction of the inner peripheral end of the corner part 25. Further, an outer peripheral end of the corner part 25 and a side surface of the cylindrical part 21 are connected by an annular connecting line 25b so that the outer peripheral end of the corner part 25 becomes a vertical direction which is the direction of the side surface 21a. Further, an apex of the suction surface 22a is indicated by an apex 22b. An annular line 22c shown in FIG. 2 is an annular line on the suction surface 22a between the connecting line 25a and the apex 22b.

As shown in FIG. 3, a plane in contact with the connecting line 25a of the suction surface 22a which is a spherical cap surface and extending outward in the radial direction is a tangential plane 22t in the tangent direction of the suction surface 22a at the connecting line 25a. Then, a circular intersecting line between the tangential plane 22t and the side surface 21a of the cylindrical part 21 forms a ridge line 25s between the suction surface 22a and the side surface 21a at the corner part 25. As described above, the ridge line 25s is an intersecting line between the tangential plane 22t of the suction surface 22a at the connecting line 25a and the side surface 21a.

Returning to FIG. 2, the opening 23 in a circular shape penetrating the upper end plate 22 is provided at the center of the upper end plate 22. The moving element 30 composed of the first push-up pin 31 and the second push-up pin 32 moves in the up-down direction so that a tip of the moving element 30 protrudes from the suction surface 22a in the opening 23. Further, a plurality of suction holes 24 communicating the suction surface 22a and the inside of the stage 20 are provided on an outer peripheral side of the opening 23. As shown in FIG. 1, the inside of the stage 20 is connected to the vacuum device 68 via the vacuum valve 64. When the vacuum valve 64 is opened, a vacuum is created at the opening 23 and the suction hole 24 as well as inside of the stage 20 by the vacuum device 68, and the lower surface 12b of the wafer sheet 12 is vacuum-sucked to the suction surface 22a.

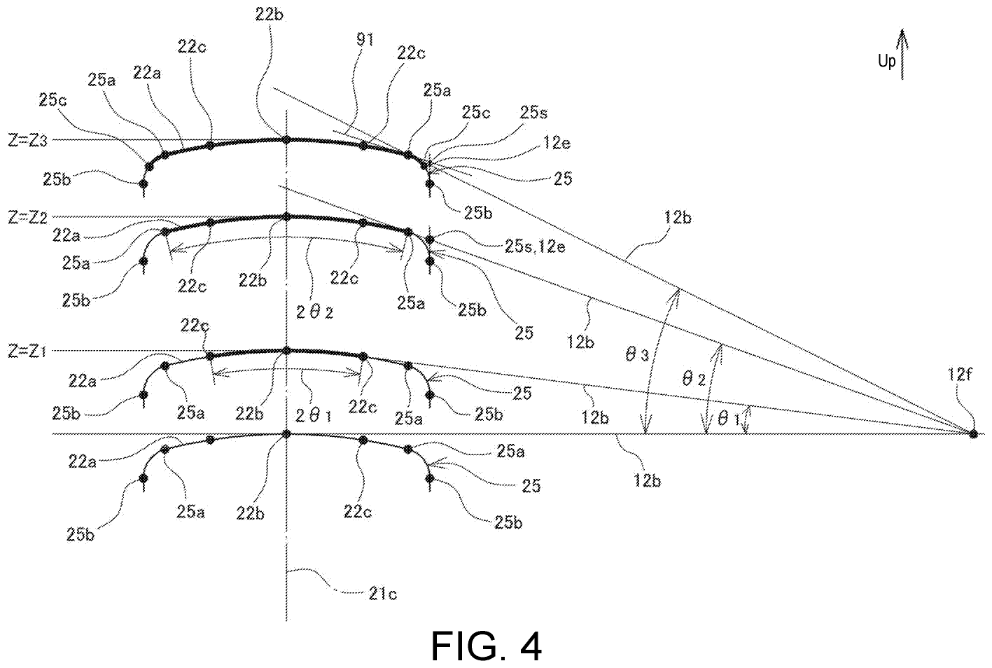

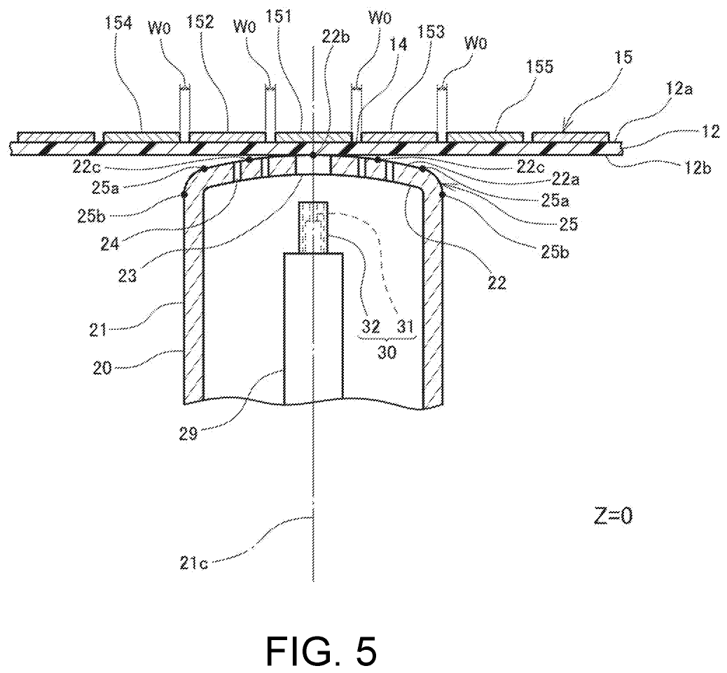

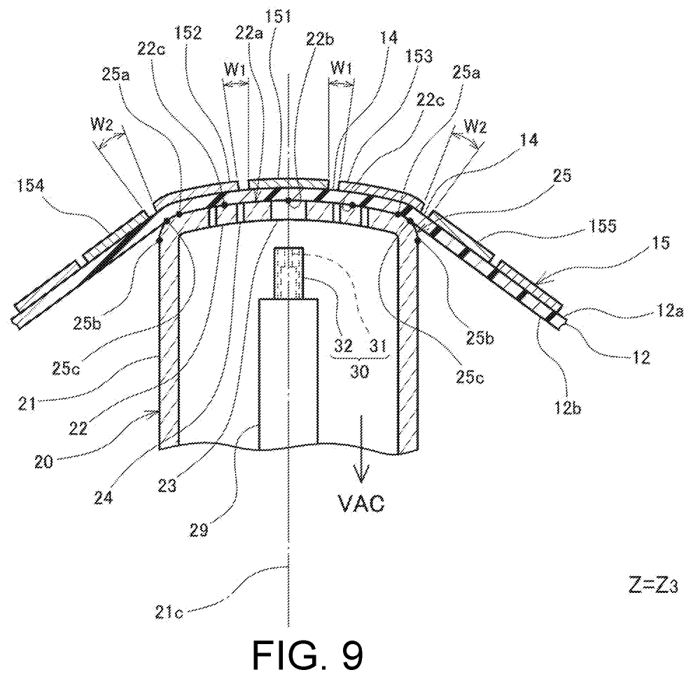

Next, an operation of picking up the semiconductor die 15 by the pickup apparatus 100 will be described with reference to FIG. 4 to FIG. 11. In the following description, the wafer sheet 12 will be described as being horizontally held on the holding surface 16a of the expanding ring 16 of the wafer holder 10 at a position where a height Z of the lower surface 12b is 0. A fixing annular line 12f shown in FIG. 4 is a line indicating an outer peripheral end of the holding surface 16a of the expanding ring 16 in contact with the lower surface 12b of the wafer sheet 12, and is a line indicating a position where the wafer sheet 12 is fixed to the holding surface 16a of the expanding ring 16. Further, as shown in FIG. 5, a plurality of semiconductor dies 151 to 155 are attached to the upper surface 12a of the wafer sheet 12, and the pickup apparatus 100 will be described to pick up the central semiconductor die 151.

As shown in the illustration of Z=0 in FIG. 4 and FIG. 5, the CPU 71 which is the processor of the control part 70 drives the wafer holder horizontal direction drive part 61 to drive the wafer holder 10 in the horizontal direction to adjust the horizontal position of the wafer holder 10 so that the semiconductor die 151 to be picked up is at a center 21c of the cylindrical part 21 of the stage 20. Then, the CPU 71 of the control part 70 drives the stage up-down direction drive part 62 to adjust the height Z of the apex 22b of the suction surface 22a of the stage 20 to the position of 0. Accordingly, as shown in FIG. 5, the center of the semiconductor die 151 is located at the center 21c of the stage 20, and the apex 22b of the suction surface 22a is in contact with the lower surface 12b of the wafer sheet 12.

Since the suction surface 22a is a spherical cap surface, in this state, only the apex 22b is in contact with the lower surface 12b of the wafer sheet 12. Further, in this state, the vacuum valve 64 is closed, the inside of the stage 20 is at atmospheric pressure, and the wafer sheet 12 is not sucked on the suction surface 22a. Therefore, in the portion other than the apex 22b, there is a gap between the suction surface 22a of the stage 20 and the lower surface 12b of the wafer sheet 12.

Further, the wafer sheet 12 is in a state extending horizontally, and a gap between upper ends of side surfaces of the semiconductor dies 151 to 155 attached to the upper surface 12a of the wafer sheet 12 is all W0.

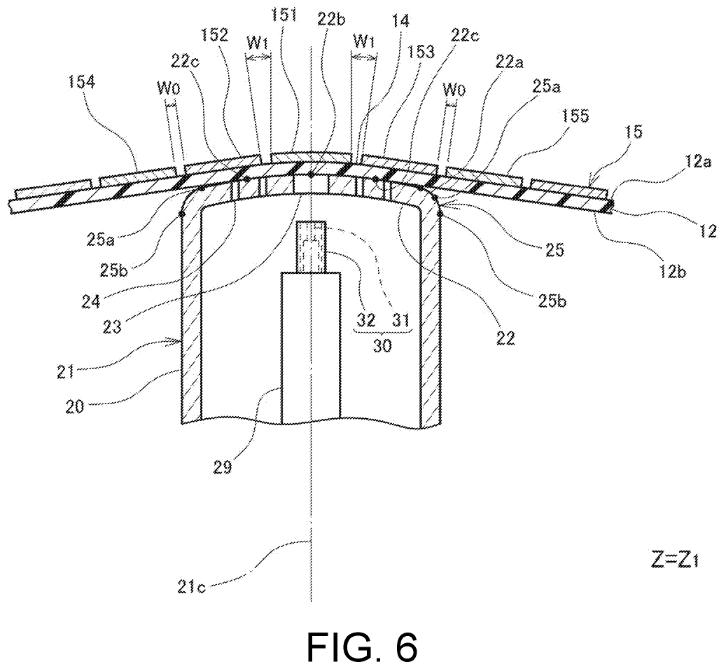

As shown in the illustration of Z=Z1 in FIG. 4 and FIG. 6, the CPU 71 of the control part 70 drives the stage up-down direction drive part 62 to raise the apex 22b of the suction surface 22a of the stage 20 to a height Z1 and push up the wafer sheet 12 (push-up process). Then, as indicated by a thick solid line in the illustration of Z=Z1 in FIG. 4, the lower surface 12b of the wafer sheet 12 is in contact with the suction surface 22a on a center side of the annular line 22c. At this time, the lower surface 12b of the wafer sheet 12 extends toward a tangential direction of the suction surface 22a at the annular line 22c, and is inclined by an angle θ1 from a plane having a height Z being 0. A region of the suction surface 22a surrounded by the annular line 22c forms a spherical cap surface which is convex upward and has a radius R1 and a central angle being 2×θ1.

The wafer sheet 12 on an inner peripheral side of the annular line 22c is deformed convexly upward along the spherical cap surface of the suction surface 22a. Therefore, a gap between the side surfaces of the semiconductor die 151 located at the center and the adjacent semiconductor die 152 increases toward the upper side, and the gap between the upper ends of the side surfaces of the semiconductor die 151 and the semiconductor die 152 widens to W1 which is wider than W0 shown in FIG. 5 Similarly, the gap between the upper ends of the side surfaces of the semiconductor die 151 and the semiconductor die 153 also widens to W1.

In this state, since the vacuum valve 64 is closed, the inside of the stage 20 is at atmospheric pressure, and the wafer sheet 12 is not sucked on the suction surface 22a, there is a gap between the suction surface 22a on an outer peripheral side of the annular line 22c and the lower surface 12b of the wafer sheet 12. Therefore, since the wafer sheet 12 on the outer peripheral side of the annular line 22c extends in a straight line toward the tangential direction of the suction surface 22a at the annular line 22c, the side surfaces of the semiconductor die 152 attached thereon and the adjacent semiconductor die 154 are parallel to each other, and the gap between the upper ends of the side surfaces remains at W0 described with reference to FIG. 5. Similarly, the gap between the upper ends of the side surfaces of the semiconductor die 153 and the adjacent semiconductor die 155 also remains at W0 described with reference to FIG. 5.

As shown in the illustration of Z=Z2 in FIG. 4, the CPU 71 of the control part 70 drives the stage up-down direction drive part 62 to raise the height Z of the apex 22b of the suction surface 22a of the stage 20 to Z2 and further push up the wafer sheet 12. Then, as indicated by a thick solid line in the illustration of Z=Z2 in FIG. 4, the lower surface 12b of the wafer sheet 12 is in contact with the suction surface 22a in a range from the apex 22b to the connecting line 25a between the suction surface 22a and the corner part 25. In this case, the lower surface 12b of the wafer sheet 12 extends toward the tangential direction of the suction surface 22a at the connecting line 25a, and is inclined by an angle θ2 from the plane having the height Z being 0. A region of the suction surface 22a surrounded by the connecting line 25a forms a spherical cap surface having a radius R1 and a central angle being 2×θ2.

In this state, there is a gap between the corner part 25 on an outer peripheral side of the connecting line 25a and the lower surface 12b of the wafer sheet 12. At this time, a height of the ridge line 25s is the same as a height of the lower surface 12b of the wafer sheet 12 at the position of the side surface 21a of the cylindrical part 21.

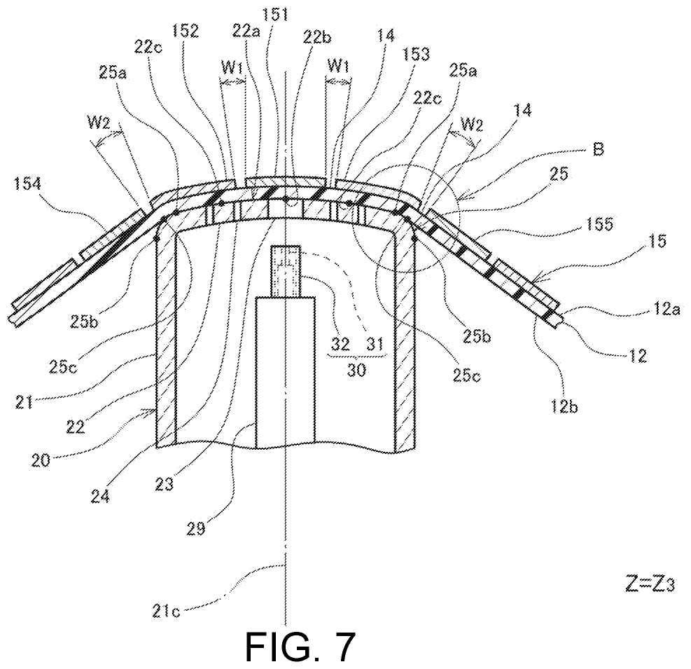

Further, as shown in the illustration of Z=Z3 in FIG. 4 and FIG. 7, the CPU 71 of the control part 70 drives the stage up-down direction drive part 62 to raise the height Z of the apex 22b of the suction surface 22a of the stage 20 to Z3 and further push up the wafer sheet 12. Then, as indicated by a thick solid line in the illustration of Z=Z3 in FIG. 4, the lower surface 12b of the wafer sheet 12 is in contact in a range from the apex 22b to the annular line 25c in the corner part 25. In this case, the lower surface 12b of the wafer sheet 12 extends toward the tangential direction of the annular line 25c of the corner part 25, and is inclined by an angle θ3 from the plane having the height Z being 0. A region surrounded by the annular line 25c forms a curved surface which is convex upward and extends from the suction surface 22a to the curved surface of the corner part 25.

Since the wafer sheet 12 on the center side of the stage 20 with respect to the annular line 25c is deformed convexly upward along the curved surface which is convex upward along the suction surface 22a and the curved surface of the corner part 25, as shown in FIG. 7, the gap between the side surfaces of the semiconductor die 152 attached thereon and the adjacent semiconductor die 154 increases toward the upper side, and the gap between the upper ends of the side surfaces of the semiconductor die 152 and the semiconductor die 154 widens to W2 which is wider than W0 described with reference to FIG. 5. Similarly, the gap between the upper ends of the side surfaces of the semiconductor die 153 and the semiconductor die 155 also widens to W2.

When the apex 20b of the stage 20 is raised to the position of the height Z3, the lower surface 12b of the wafer sheet 12 is in contact with a portion of the curved surface of the corner part 25 on the outer side of the connecting line 25a, which is the outer peripheral end of the suction surface 22a. Since the radius R2 of this portion is smaller than the radius R1 of the suction surface 22a, a bend radius in the vicinity of the annular line 25c of the wafer sheet 12 is smaller than a bend radius of the wafer sheet 12 bent along the suction surface 22a. Therefore, a spread angle of the gap between the side surfaces of the semiconductor die 152 and the adjacent semiconductor die 154 is larger than a spread angle of the gap between the side surfaces of the semiconductor die 151 and the semiconductor die 152. Therefore, the gap W2 is wider than the gap W1.

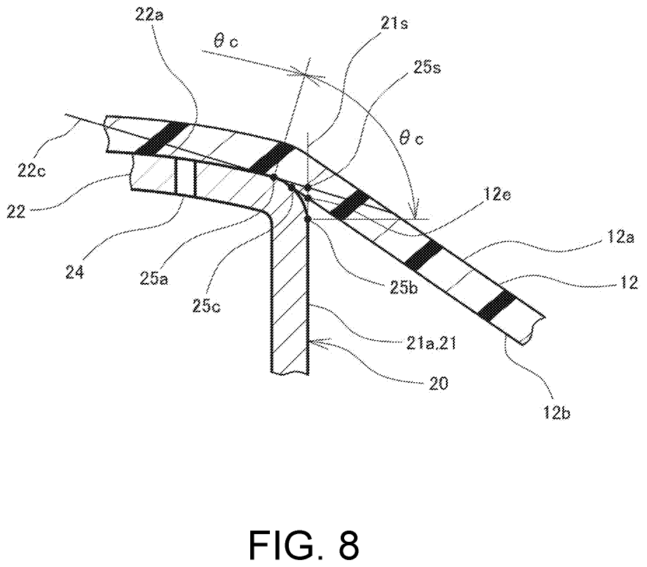

In this state, since the vacuum valve 64 is closed, the inside of the stage 20 is at atmospheric pressure, and the wafer sheet 12 is not sucked on the suction surface 22a, there is a gap between the corner part 25 on the outer peripheral side of the annular line 25c and the lower surface 12b of the wafer sheet 12. Further, as shown in FIG. 8, at this time, the height of the ridge line 25s is greater than a height 12e of the lower surface 12b of the wafer sheet 12 at the position of the side surface 21a of the cylindrical part 21.

Next, the CPU 71 of the control part 70 opens the vacuum valve 64 to create a vacuum inside the stage 20. Accordingly, a vacuum is created at the opening 23 and the plurality of suction holes 24, and the lower surface 12b of the wafer sheet 12 is vacuum-sucked to the suction surface 22a (suction process).

When the apex 22b of the stage 20 is raised to the height Z3, as described with reference to FIG. 7, the lower surface 12b of the wafer sheet 12 is in contact with the spherical cap surface of the suction surface 22a and the curved surface of the corner part 25 in a state of being deformed convexly upward along the spherical cap surface of the suction surface 22a and the curved surface of the corner part 25. Therefore, when a vacuum is created inside the stage 20 and the lower surface 12b of the wafer sheet 12 is vacuum-sucked onto the suction surface 22a, the wafer sheet 12 remains in the same state of being deformed convexly upward as before the vacuum suction. Accordingly, even though the lower surface 12b of the wafer sheet 12 is vacuum-sucked to the suction surface 22a, as described with reference to FIG. 7, the gap between the upper ends of the semiconductor dies 151 to 155 remains at W1 and W2 which are wider than the initial W0.

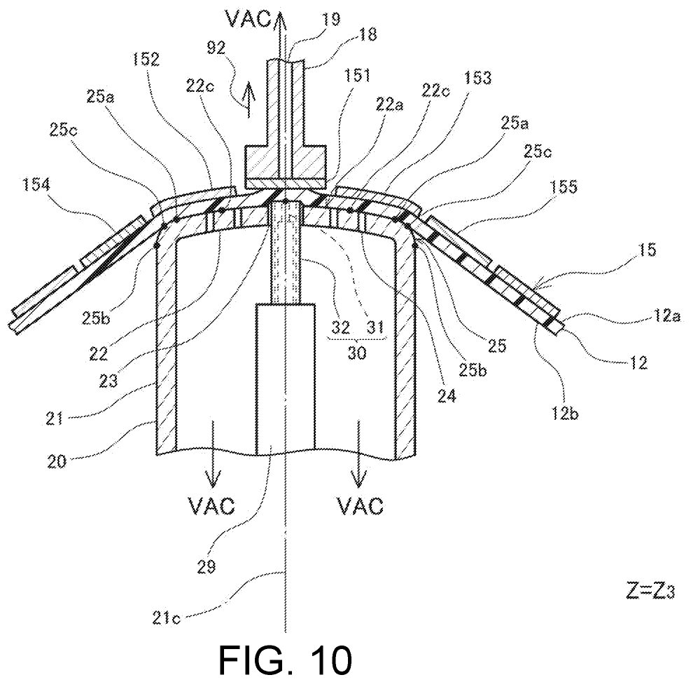

Next, the CPU 71 of the control part 70 moves the collet 18 onto the semiconductor die 151 by the collet drive part 63, and opens the vacuum valve 65 to create a vacuum at the suction hole 19 of the collet 18 and vacuum-suck the collet 18 to the semiconductor die 151. Then, the CPU 71 of the control part 70 drives the moving element drive mechanism 29 to integrally move the first push-up pin 31 and the second push-up pin 32 upward as shown in FIG. 10 and protrude each tip from the suction surface 22a to push up the semiconductor die 151, and raises the collet 18 in accordance with the rise of the first push-up pin 31 and the second push-up pin 32.

Accordingly, a lead for peeling between the wafer sheet 12 and the semiconductor die 151 is generated at the peripheral edge of the semiconductor die 151. At this time, a small peeling of the peripheral edge of the semiconductor die 151 may be generated.

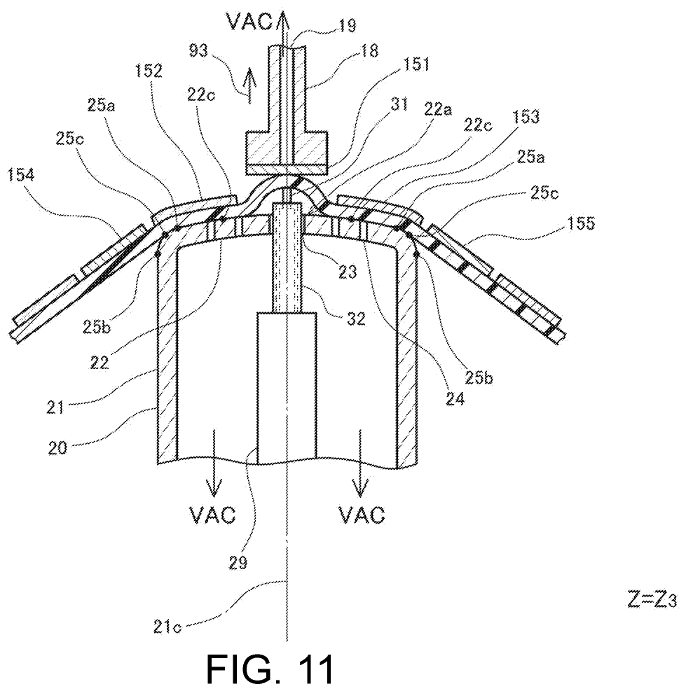

Then, as shown in FIG. 11, the CPU 71 of the control part 70 further raises the first push-up pin 31 to push up the semiconductor die 151, and raises the collet 18 in accordance with the rise of the first push-up pin 31 to pick up the semiconductor die 151 by the collet 18 (pickup process).

As described above, in the pickup apparatus 100 of the embodiment, since the suction surface 22a of the stage 20 is a spherical cap surface which is convex upward, as shown in FIG. 5 to FIG. 7, as the stage 20 is raised, the wafer sheet 12 is deformed convexly upward along the spherical cap surface of the suction surface 22a and the curved surface of the corner part 25, and when the height Z of the stage 20 is raised to Z3 as shown in FIG. 7 and FIG. 8, the gap between the upper ends of the side surfaces of the semiconductor dies 151 to 155 widens to W1 and W2 which are wider than the initial W0.

Further, when the stage 20 is raised to the height Z3, the lower surface 12b of the wafer sheet 12 is in contact with the spherical cap surface of the suction surface 22a and the curved surface of the corner part 25 in a state of being deformed convexly upward along the spherical cap surface of the suction surface 22a and the curved surface of the corner part 25. Therefore, when a vacuum is created inside of the stage 20 and the lower surface 12b of the wafer sheet 12 is vacuum-sucked onto the suction surface 22a, the wafer sheet 12 remains deformed convexly upward, and the gap between the upper ends of the semiconductor dies 151 to 155 remains at W1 and W2 which are wider than the initial W0. Accordingly, it is possible to prevent the upper ends of the side surfaces of the adjacent semiconductor dies 151 to 155 from coming into contact with each other during the pickup operation and thus causing chipping or cracking.

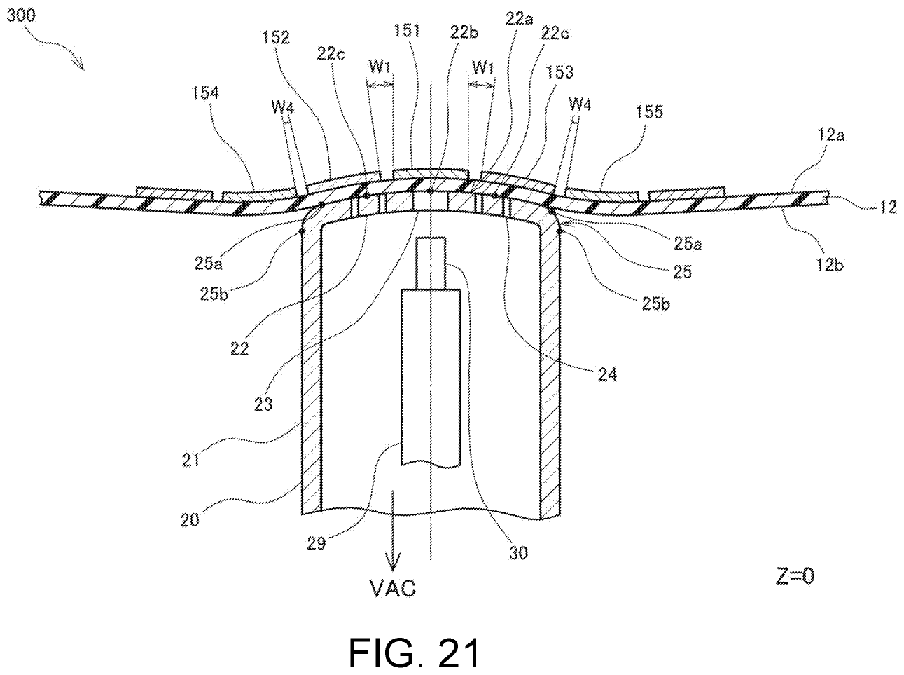

In contrast, as in a pickup apparatus 300 of a comparative example shown in FIG. 21, when the wafer sheet 12 is vacuum-sucked with the height Z of the apex 22b of the suction surface 22a being 0 before the stage 20 is raised, the wafer sheet 12 is deformed convexly upward along the spherical cap surface which is convex upward on the suction surface 22a. At this time, the lower surface 12b of the wafer sheet 12 deforms downward from the height Z being 0. As described with reference to FIG. 4, the wafer sheet 12 is fixed to the expanding ring 16 at the fixing annular line 12f having a height Z being 0. Accordingly, on the outer side of the suction holes 24 on the outer peripheral side where vacuum suction is not performed, the wafer sheet 12 extends upward toward the fixing annular line 12f having a height Z being 0. Therefore, at the peripheral edge of the stage 20, the wafer sheet 12 is curved and deformed convexly downward. Then, the side surfaces of the semiconductor die 153 attached on the wafer sheet 12 which is curved and deformed convexly downward and the adjacent semiconductor die 155 become narrower toward the upper side, and the width of the gap between the upper ends of the side surfaces is reduced from the initial width W0 shown in FIGS. 5 to W4 which is narrower than W0. Therefore, in the pickup apparatus 300 of a semiconductor die shown in FIG. 21, when the semiconductor dies 151 to 155 are picked up, the upper ends of the side surfaces of the semiconductor die 153 located at the peripheral edge of the stage 20 and the adjacent semiconductor die 155 may come into contact with each other, thus causing chipping or cracking. Particularly, when the initial width W0 is narrow, there is a high possibility that chipping or cracking would occur in the semiconductor dies 153 and 155.

In contrast, in the pickup apparatus 100 of the embodiment, as described above, since the wafer sheet 12 is vacuum-sucked to the suction surface 22a after the stage 20 is raised until the lower surface 12b of the wafer sheet 12 comes into contact with the spherical cap surface of the suction surface 22a and the curved surface of the corner part 25, the wafer sheet 12 remains deformed convexly upward, and the wafer sheet 12 is prevented from being deformed convexly downward. Accordingly, the gap between the upper ends of the semiconductor dies 151 to 155 remains at W1 and W2 which are wider than the initial W0, and during the pickup operation, it is possible to prevent the upper ends of the side surfaces of the adjacent semiconductor dies 151 to 155 from coming into contact with each other and thus causing chipping or cracking.

In the above description, the control part 70 raises the apex 20b of the stage 20 to the height Z3, but the present invention is not limited thereto and the height may be Z2 or higher; for example, after the apex 22b of the stage 20 is raised to the height Z2, the wafer sheet 12 may be vacuum-sucked to the suction surface 22a.

In this case, since the wafer sheet 12 does not hang on the curved surface of the corner part 25, the spread angle of the gap between the side surfaces of the semiconductor die 153 and the adjacent semiconductor die 155 is smaller than in the case where the stage 20 is raised to the height Z3, and the gap between the upper ends of the side surfaces of the semiconductor die 151 and the semiconductor die 152 is W3 which is wider than W0 and narrower than W2. This will be described in detail later in the description of another embodiment.

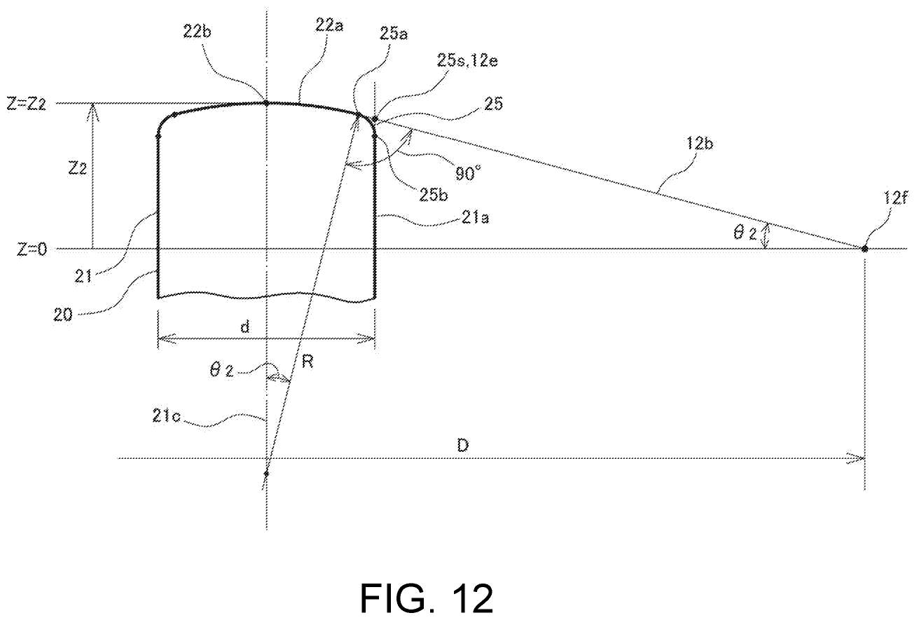

As the structure of the pickup apparatus 100 and the pickup operation of the semiconductor die 151 of the embodiment have been described above, next, a design example of the stage 20 of the pickup apparatus 100 will be briefly described with reference to FIG. 12.

FIG. 12 shows a state in which the apex 22b of the suction surface 22a of the stage 20 is raised to the height Z2, as in the case of the illustration of Z=Z2 in FIG. 4. In FIG. 12, the diameter of the stage 20 is d, and the diameter of the fixing annular line 12f of the expanding ring 16 fixing the wafer sheet 12 is D.

The lower surface 12b of the wafer sheet 12 extends obliquely upward at an angle θ2 with respect to the horizontal line having a height Z being 0, and is in contact with the connecting line 25a which is the outer peripheral end of the suction surface 22a. Since the diameter D of the fixing annular line 12f is 300 mm, the diameter d of the stage 20 is 8 mm, and D is larger than d,

tan(θ2)≈2×Z2/D (1).

From Formula (1), the angle θ2 is

θ2=tan⁻¹(2×Z2/D) (2).

Further, since R2 of the corner part 25 is about 0.1 to 0.5 mm, which is much smaller than the diameter d of the stage 20,

sin(θ2)≈(d/2)/R≈θ2 (3).

From Formula (1) and Formula (3),

d/(2×R)=tan⁻¹(2×Z2/D) (4)

R=d/2×tan⁻¹(2×Z2/D) (5)

Herein, if Z2=1 mm, D=300 mm, and d=8 mm, then R≈600 mm.

That is, in the case of the stage 20 having a diameter of 8 mm, assuming that the radius R1 of the spherical cap surface of the suction surface 22a is 600 mm, the stage 20 may be raised by 1 mm, and then a vacuum may be created inside the stage 20 to suck the wafer sheet 12.

Regardless of the design example described above, the radius R1 and the raise amount of the stage 20 may be freely set in each pickup apparatus of a semiconductor die.

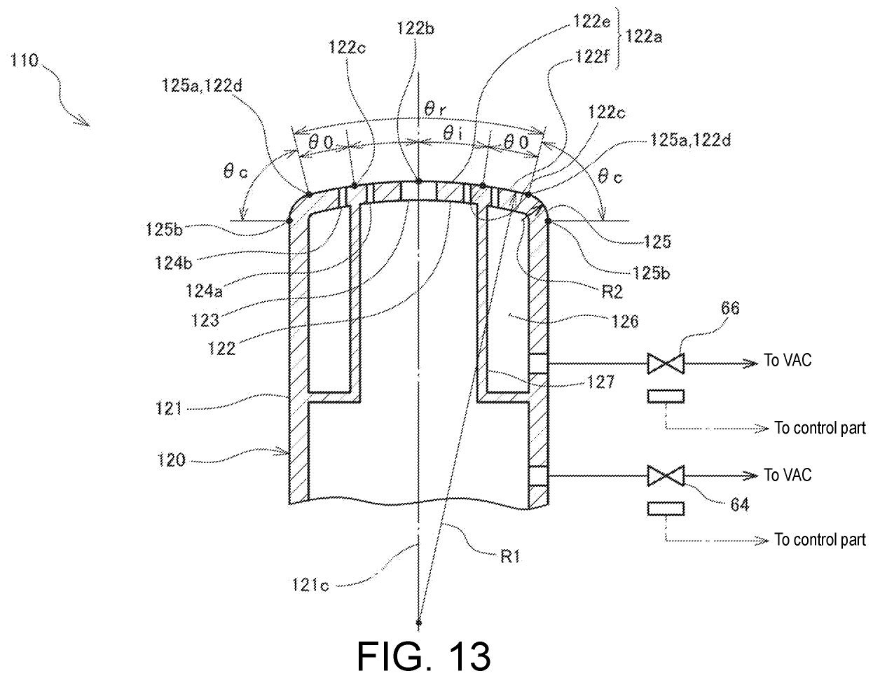

Next, a configuration of a pickup apparatus 110 of a semiconductor die (hereinafter referred to as a pickup apparatus 110) of another embodiment will be described with reference to FIG. 13. The same parts as those of the pickup apparatus 100 described above with reference to FIG. 1 will be labeled with the same reference signs, and descriptions thereof will be omitted.

As shown in FIG. 13, the pickup apparatus 110 has the same configuration as the pickup apparatus 100 described above with reference to FIG. 1 and FIG. 2 except that the configuration of a stage 120 is different from the configuration of the stage 20 of the pickup apparatus 100 described above.

A suction surface 122a of the stage 120 is composed of an inner peripheral part 122e around an opening 123 provided at a center, and an outer peripheral part 122f on an outer side of the inner peripheral part 122e, and the inner peripheral part 122e is provided with an inner suction hole 124a, and the outer peripheral part 122f is provided with an outer suction hole 124b. The suction surface 122a is a spherical cap surface having a radius R1 and a central angle being θr, as in the stage 20 described above with reference to FIG. 2. The suction surface 122a and a side surface 121a of a cylindrical part 121 are connected by a corner part 125 composed of a curved surface having a radius R2 and an angle θc.

An outer peripheral end of the suction surface 122a and an inner peripheral end of the corner part 125 are connected by an annular connecting line 125a so that a tangential direction of the outer peripheral end of the suction surface 122a becomes a tangential direction of the inner peripheral end of the corner part 125. The connecting line 125a is also an annular line 122d indicating the outer peripheral end of the suction surface 122a. Further, an outer peripheral end of the corner part 125 and the side surface of the cylindrical part 21 are connected by an annular connecting line 125b.

Herein, the inner peripheral part 122e is in a range of the suction surface 122a on an inner side of an annular line 122c between the inner suction hole 124a and the outer suction hole 124b, and is a spherical cap surface having a radius R1 and a central angle θi. The annular line 122c is an annular line which defines an outer peripheral end of the inner peripheral part 122e. Similar to the annular line 22c of the stage 20, the annular line 122c is arranged at a position where a tangential direction of the suction surface 122a at the annular line 122c is an extending direction of the lower surface 12b of the wafer sheet 12 when an apex 122b is raised to a height Z1.

The outer peripheral part 122f is in a range from the annular line 122 which is the outer peripheral end of the inner peripheral part 122e to the annular line 122d or the connecting line 125a which indicates the outer peripheral end of the suction surface 122a. The outer peripheral part 122f is a spherical segment surface having a radius R1 and an angle being θ0.

The inner suction hole 124a communicates with the inside of the cylindrical part 21 of the stage 20, and when the vacuum valve 64 attached to a pipe connected to the cylindrical part 21 is opened, a vacuum is created at the inner suction hole 124a as well as the opening 123 by the vacuum device 68.

The outer suction hole 124b communicates with an outer cavity 126 surrounded by a partition wall 127 provided inside the cylindrical part 21 of the stage 20. When a vacuum valve 66 attached to a pipe connected to the outer cavity 126 is opened, a vacuum is created at the outer suction hole 124b by the vacuum device 68. The outer cavity 126 does not communicate with the opening 123 and the inner suction hole 124a. Therefore, by opening and closing the vacuum valves 64 and 66, the inner suction hole 124a and the outer suction hole 124b can be separately switched between a vacuum state and an atmospheric pressure state.

Herein, similar to the vacuum valve 64, the vacuum valve 66 is connected to the control part 70 and operates according to a command of the control part 70.

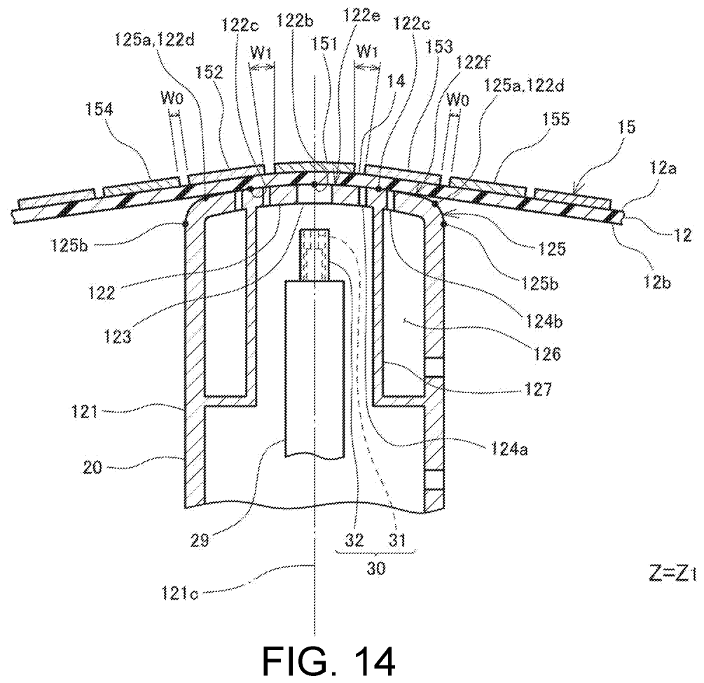

Next, a first pickup operation of the pickup apparatus 110 will be described with reference to FIG. 14 to FIG. 17. The first pickup operation includes the following: after a push-up process of raising the apex 122b of the stage 120 to the height Z1 to push up the wafer sheet 12, a vacuum is created at the inner suction hole 124a of the stage 120 and the lower surface 12b of the wafer sheet 12 is sucked to the inner peripheral part 122e of the suction surface 122a (suction process), and afterwards, the semiconductor die 151 is picked up.

As shown in FIG. 14, the CPU 71 of the control part 70 drives the stage up-down direction drive part 62 to raise the apex 122b of the stage 120 to the height Z1 to push up the wafer sheet 12.

As described above, the annular line 122c is arranged at a position where a tangential direction of the suction surface 122a at the annular line 122c becomes an extending direction of the lower surface 12b of the wafer sheet 12 when the apex 122b is raised to the height Z1. Therefore, when the apex 122b is raised to the height Z1, as in the case described with reference to FIG. 6, the lower surface 12b of the wafer sheet 12 is in contact with the inner peripheral part 122e of the suction surface 122a on the center side of the annular line 122c. At this time, the lower surface 12b of the wafer sheet 12 extends toward the tangential direction of the suction surface 122a at the annular line 122c. The wafer sheet 12 is deformed convexly upward along the inner peripheral part 122e of the suction surface 122a. Therefore, the gap between the side surfaces of the semiconductor die 151 located at the center and the adjacent semiconductor die 152 increases toward the upper side, and the gap between the upper ends of the side surfaces of the semiconductor die 151 and the semiconductor die 152 widens to W1 which is wider than W0 shown in FIG. 5. Similarly, the gap between the upper ends of the side surfaces of the semiconductor die 151 and the semiconductor die 153 also widens to W1.

In this state, the vacuum valves 64 and 66 are closed, the inside of the stage 120 and the outer cavity 126 are at atmospheric pressure, both the inner suction hole 124a and the outer suction hole 124b are at atmospheric pressure, and the wafer sheet 12 is not sucked onto the inner peripheral part 122e and the outer peripheral part 122f. Therefore, there is a gap between the outer peripheral part 122f on the outer periphery of the annular line 122c and the lower surface 12b of the wafer sheet 12. Further, since the wafer sheet 12 on the upper side of the outer peripheral part 122f on the outer peripheral side of the annular line 122c extends in a straight line toward the tangential direction at the annular line 122c, the side surfaces of the semiconductor die 152 attached to the upper surface 12a of the wafer sheet 12 located above the outer peripheral part 122f and the adjacent semiconductor die 154 are parallel to each other, and the gap between the upper ends of the side surfaces remains at W0 as described with reference to FIG. 5. Similarly, the gap between the upper ends of the side surfaces of the semiconductor die 153 and the adjacent semiconductor die 155 also remains at W0 as described with reference to FIG. 5.

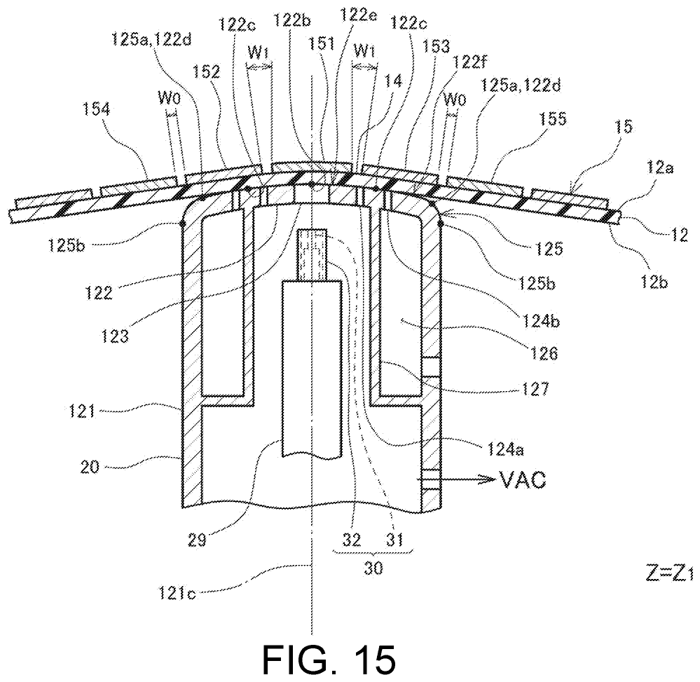

Next, the CPU 71 of the control part 70 opens the vacuum valve 64, as shown in FIG. 15, to create a vacuum at the opening 123 and the inner suction hole 124a and vacuum-suck the lower surface 12b of the wafer sheet 12 to the inner peripheral part 122e of the suction surface 122a. Since the lower surface 12b of the wafer sheet 12 is in contact with the inner peripheral part 122e, the wafer sheet 12 on the upper side of the inner peripheral part 122e remains convex upward even though it is vacuum-sucked, and the gap between the upper ends of the side surfaces of the semiconductor die 151 and the semiconductor die 152 and the gap between the upper ends of the side surfaces of the semiconductor die 151 and the semiconductor die 153 remain at W1.

On the other hand, since the CPU 71 of the control part 70 keeps the vacuum valve 66 in a closed state, the outer cavity 126 and the outer suction hole 124b are not a vacuum but remain at atmospheric pressure. Therefore, the wafer sheet 12 on the upper side of the outer peripheral part 122f remains in a state of extending in a straight line toward the tangential direction at the annular line 122c, and the gap between the upper ends of the side surfaces of the semiconductor die 152 and the adjacent semiconductor die 154 and the gap between the upper ends of the side surfaces of the semiconductor die 153 and the adjacent semiconductor die 153 remain at W0.

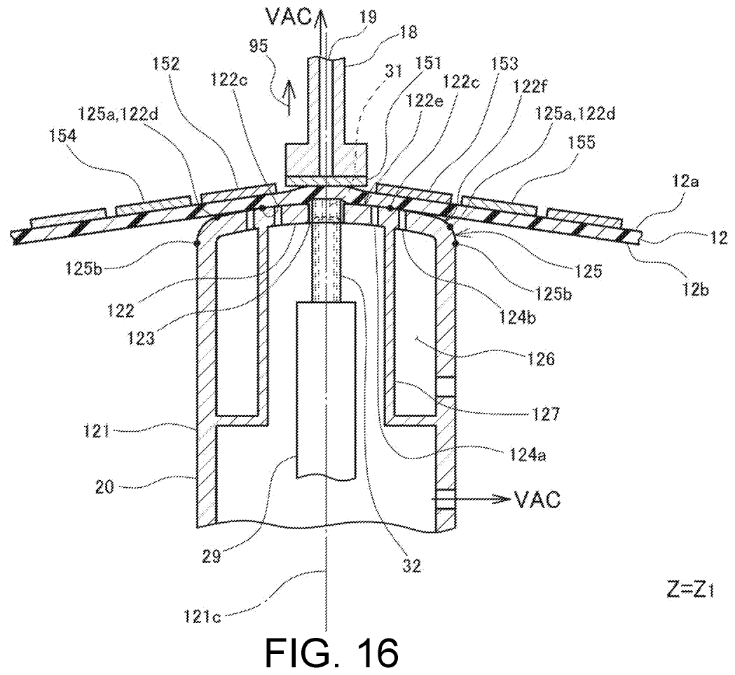

Next, as shown in FIG. 16, the CPU 71 of the control part 70, as in the case described above with reference to FIG. 10, moves the collet 18 onto the semiconductor die 151, and vacuum-sucks the collet 18 to the semiconductor die 151. Then, the first push-up pin 31 and the second push-up pin 32 are integrally moved upward to push up the semiconductor die 151, and the collet 18 is raised in accordance with the rise of the first push-up pin 31 and the second push-up pin 32 to generate a lead for peeling between the wafer sheet 12 and the semiconductor die 151 at the peripheral edge of the semiconductor die 151.

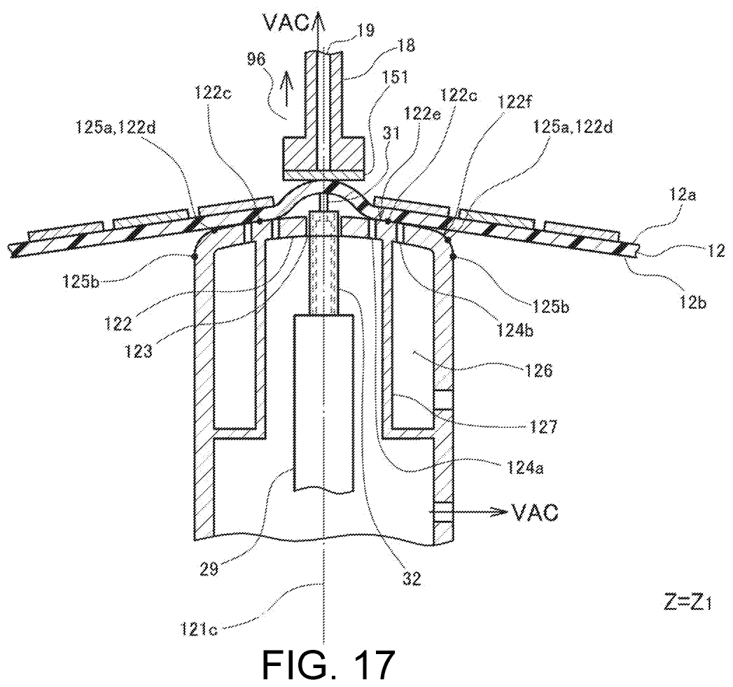

Then, as shown in FIG. 17, the CPU 71 of the control part 70 further raises the first push-up pin 31 to push up the semiconductor die 151 and raises the collet 18 in accordance with the rise of the first push-up pin 31 to pick up the semiconductor die 151 by the collet 18 (pickup process).

As described above, the pickup apparatus 110 of the embodiment raises the apex 122b of the stage 120 to the height Z1 so that the wafer sheet 12 is in contact with the inner peripheral part 122e of the suction surface 122a, deforms the wafer sheet 12 to be convex upward along the inner peripheral part 122e, and widens the gap between the upper ends of the side surface of the semiconductor die 151 attached on the inner peripheral part 122e and the side surfaces of the adjacent semiconductor dies 152 and 153 to W1 which is wider than the initial W0. Further, the outer suction hole 124b remains at atmospheric pressure, the wafer sheet 12 located above the outer peripheral part 122f remains separated from the outer peripheral part 122f of the suction surface 122a, the gap between the upper ends of the side surfaces of the semiconductor dies 152 and 153 attached to the upper surface 12a of the wafer sheet 12 located on the upper side of the outer peripheral part 122f and the adjacent semiconductor dies 154 and 155 remains at the initial W0.

Accordingly, it is possible to suppress occurrence of the following: during the pickup operation, the wafer sheet 12 is curved and deformed convexly downward, the gap between the upper ends of the side surfaces of the adjacent semiconductor dies 151 to 155 becomes smaller, and the upper ends of the side surfaces of the semiconductor dies 151 to 155 come into contact with each other thus causing chipping or cracking, as in the case of the pickup apparatus 300 described with reference to FIG. 21.

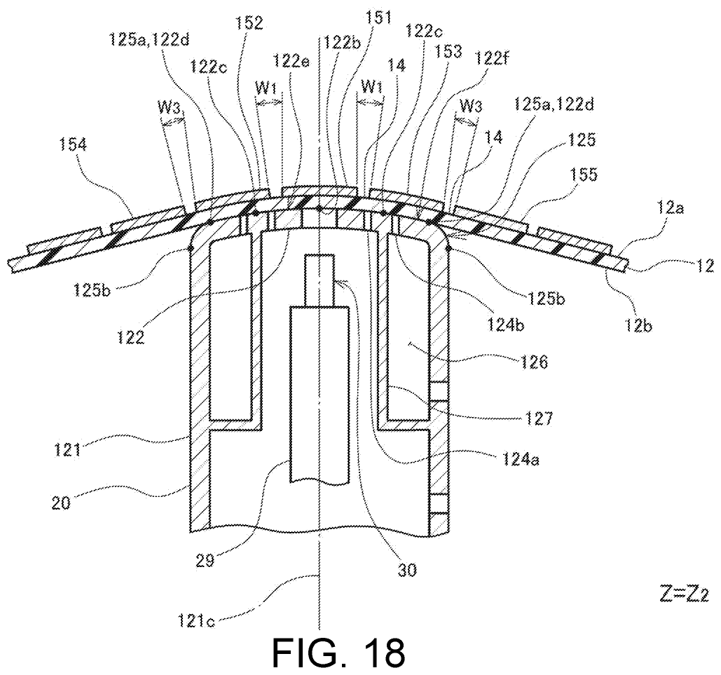

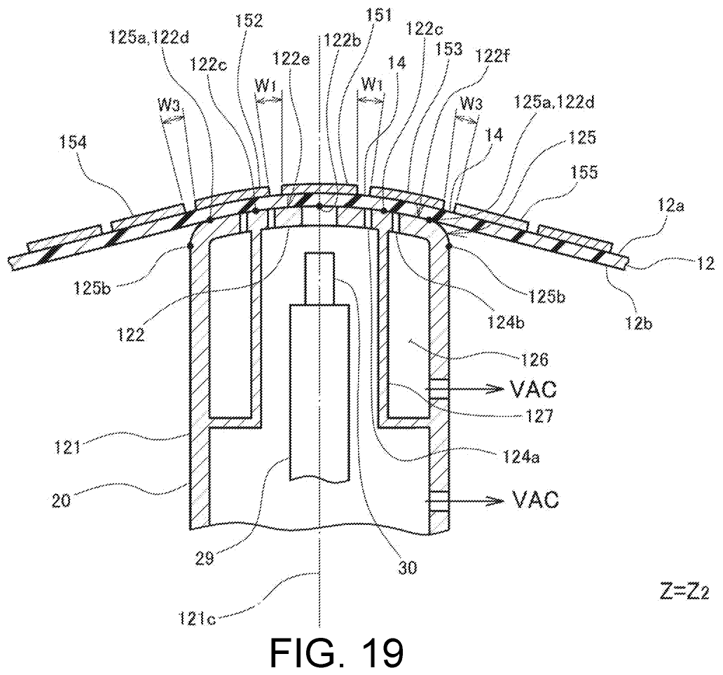

Next, a second pickup operation of the pickup apparatus 110 of another embodiment will be described with reference to FIG. 18 and FIG. 19. The second pickup operation includes the following: after the height Z of the apex 122b of the stage 120 is raised to Z2, a vacuum is created at both the inner suction hole 124a and the outer suction hole 124b to vacuum-suck the wafer sheet 12 to the inner peripheral part 122e and the outer peripheral part 122f of the suction surface 122a, and afterwards, the semiconductor die 151 is picked up.

As shown in FIG. 18, the CPU 71 of the control part 70 raises the apex 122b of the stage 120 to the height Z2. As described with reference to FIG. 4, the height Z2 is a height of the stage 120 at which the lower surface 12b of the wafer sheet 12 is in contact with the suction surface 122a in a range from the apex 122b to the connecting line 125a between the suction surface 122a and the corner part 125. Therefore, when the apex 122b of the stage 120 is raised to the height Z2, the lower surface 12b of the wafer sheet 12 is in contact with the inner peripheral part 122e and the outer peripheral part 122f of the suction surface 122a. Then, the lower surface 12b of the wafer sheet 12 extends toward a tangential direction of the suction surface 122a at the annular line 122d or the connecting line 125a which is the outer peripheral end of the outer peripheral part 122f. In this state, there is a gap between the corner part 125 on the outer peripheral side of the connecting line 125a and the lower surface 12b of the wafer sheet 12.

As shown in FIG. 18, the gap 14 between the semiconductor die 153 and the semiconductor die 155 is located on the upper surface 12a of the wafer sheet 12 in contact with the outer peripheral part 122f. On the other hand, the semiconductor die 155 is located on the upper surface 12a of the wafer sheet 12 extending toward the tangential direction of the suction surface 122a at the connecting line 125a. Therefore, while the gap between the upper ends of the side surface of the semiconductor die 153 and the side surface of the adjacent semiconductor die 155 is wider than the initial W0 shown in FIG. 5, the opening degree of the gap is W3, i.e., about half of that in the case where both are located on the upper surface 12a of the wafer sheet 12 in contact with the suction surface 122a, as in the case of the semiconductor die 151 and the adjacent semiconductor die 153 (W3≈W0+(W1−W0)/2). Similarly, the gap between the upper ends of the side surfaces of the semiconductor die 152 and the semiconductor die 154 is W3.

In this state, the CPU 71 of the control part 70 opens the vacuum valves 64 and 66 to create a vacuum at the inner suction hole 124a and the outer suction hole 124b and vacuum-suck the lower surface 12b of the wafer sheet 12 to the inner peripheral part 122e and the outer peripheral part 122f of the suction surface 122a.

Since the lower surface 12b of the wafer sheet 12 is in contact with the inner peripheral part 122e, the wafer sheet 12 on the upper side of the inner peripheral part 122e and the outer peripheral part 122f remains convex upward even though it is vacuum-sucked, and the gap between the upper ends of the side surfaces of the semiconductor die 151 and the semiconductor die 152 and the gap between the upper ends of the side surfaces of the semiconductor die 151 and the semiconductor die 153 remain at W1. Further, since the lower surface 12b of the wafer sheet 12 on the outer side of the outer peripheral part 122f is kept in a state of extending toward the tangential direction of the suction surface 122a at the annular line 122d or the connecting line 125a which is the outer peripheral end of the outer peripheral part 122f, the gap between the upper ends of the side surfaces of the semiconductor die 152 and the semiconductor die 154 and the gap between the upper ends of the side surfaces of the semiconductor die 153 and the semiconductor die 155 remain at a width of W3 which is wider than W0.

Accordingly, similar to the case of the first pickup operation described with reference to FIG. 16 and FIG. 17, it is possible to suppress occurrence of the following: during the pickup operation, the wafer sheet 12 is curved and deformed convexly downward, the gap between the upper ends of the side surfaces of the adjacent semiconductor dies 151 to 155 becomes smaller, and the upper ends of the side surfaces of the semiconductor dies 151 to 155 come into contact with each other, thus causing chipping or cracking.

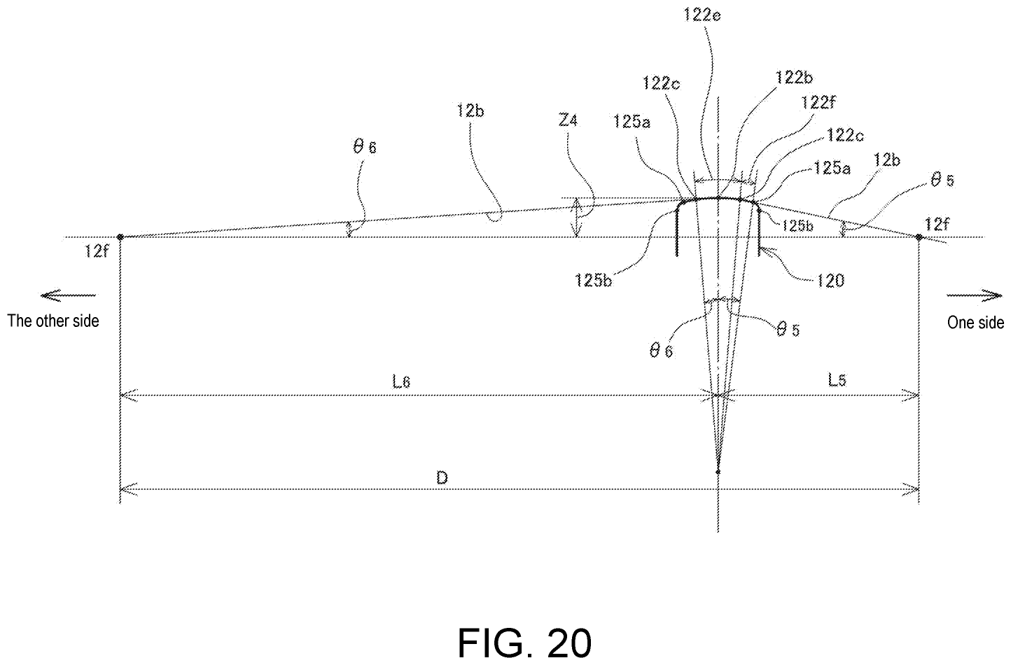

Next, the use of the first pickup operation and the second pickup operation in the pickup apparatus 110 will be described with reference to FIG. 20. While the positional relationship between the stage 120 and the wafer sheet 12 when the stage 120 is located at the center of the expanding ring 16 and pushes up the center of the wafer sheet 12 is as described with reference to FIG. 12, herein, a case where the stage 120 comes to a position deviated from the center of the expanding ring 16 will be described with reference to FIG. 20.

As shown in FIG. 20, the following case is considered: a center 121c of the stage 120 is deviated from the center of the expanding ring 16, a distance from the center 121c to the fixing annular line 12f on one side is L5, a distance on the other side is L6, and herein L5<L6.

In this case, when the apex 122b of the stage 120 is raised to a height Z4, as shown in FIG. 20, on one side, an angle θ5 of the lower surface 12b of the wafer sheet 12 with respect to the horizontal line of Z=0 is large, and the lower surface 12b of the wafer sheet 12 is in contact with the inner peripheral part 122e and the outer peripheral part 122f of the suction surface 122a; on the other side, an angle θ6 of the lower surface 12b of the wafer sheet 12 with respect to the horizontal line of Z=0 is smaller than the angle θ5, and although the lower surface 12b of the wafer sheet 12 is in contact with the inner peripheral part 122e of the suction surface 122a, the lower surface 12b of the wafer sheet 12 is not in contact with the outer peripheral part 122f on the outer side of the annular line 122c. In this case, there is a gap between the outer peripheral part 122f on the other side and the lower surface 12b of the wafer sheet 12.

In this state, as in the second pickup operation, when a vacuum is created at the inner suction hole 124a and the outer suction hole 124b, the wafer sheet 12 located with a gap opened on the outer peripheral part 122f on the other side is pulled downward and sucked on the outer peripheral part 122f. Therefore, the wafer sheet 12 is curved and deformed convexly downward at the peripheral edge of the stage 20 as in the pickup apparatus 300 of the comparative example described with reference to FIG. 21. Therefore, the upper ends of the side surfaces of the semiconductor die 152 located at the peripheral edge of the stage 20 and the adjacent semiconductor die 154 may come into contact with each other, thus causing chipping or cracking.

Therefore, in the pickup apparatus 110, when the stage 20 is deviated from the center of the expanding ring 16 and the semiconductor die 151 attached to the outer peripheral portion of the wafer sheet 12 is to be picked up, as in the first pickup operation, a vacuum may be created only at the inner suction hole 124a without creating a vacuum at the outer suction hole 124b to pick up the semiconductor die 151, and when the semiconductor die 151 attached to the central portion of the wafer sheet 12 is to be picked up, as in the second pickup operation, a vacuum may be created at the inner suction hole 124a and the outer suction hole 124b to pick up the semiconductor die 151.

Accordingly, also in the case of picking up the semiconductor die 151 attached to the peripheral portion of the wafer sheet 12, it is possible to prevent the upper ends of the side surfaces of the semiconductor die 152 located at the peripheral edge of the stage 20 and the adjacent semiconductor die 155 from coming into contact with each other, thus causing chipping or cracking.

In the above description, although the suction surface 122a has been described as being divided into two parts, including the inner peripheral part 122e provided with the inner suction hole 124a and the outer peripheral part 122f provided with the outer suction hole 124b, the present invention is not limited thereto, and for example, an intermediate part may also be provided between the inner peripheral part 122e and the outer peripheral part 122f to divide the suction surface 122a into three parts and change the region for vacuum-sucking the wafer sheet 12 according to the amount of deviation of the stage 20 from the center of the expanding ring 16.

Further, the inner peripheral part 122e provided with the inner suction hole 124a and the outer peripheral part 122f provided with the outer suction hole 124b may also be divided into a plurality of parts in the circumferential direction to change the region for vacuum-sucking the wafer sheet 12 according to the position of the center of the stage 20 with respect to the center of the expanding ring 16.

### REFERENCE SIGNS LIST

10 Wafer holder; 11 Wafer; 12 Wafer sheet; 12a Upper surface; 12b Lower surface; 12f Fixing annular line; 13 Ring; 14 Gap; 15, 151 to 155 Semiconductor die; 16 Expanding ring; 18 Collet; 19 Suction hole; 20, 120 Stage; 20b, 120b Apex; 21, 121 Cylindrical part; 21a, 121a Side surface; 21c, 121c Center; 22, 122 Upper end plate; 22a, 122a Suction surface; 22b, 122b Apex; 22c, 25c, 122c, 122d, 125c Annular line; 22t Tangential plane; 23, 123 Opening; 24, 124 Suction hole; 25, 125 Corner part; 25a, 25b, 125a, 125b Connecting line; 25s, 125s Ridge line; 29 Moving element drive mechanism; 30 Moving element; 31 First push-up pin; 32 Second push-up pin; 61 Wafer holder horizontal direction drive part; 62 Stage up-down direction drive part; 63 Collet drive part; 64, 65, 66 Vacuum valve; 68 Vacuum device; 70 Control part; 71 CPU; 72 Memory; 100, 110, 300 Pickup apparatus; 122e Inner peripheral part; 122f Outer peripheral part; 124a Inner suction hole; 124b Outer suction hole; 126 Outer cavity; 127 Partition wall

1. A pickup apparatus of a semiconductor die which picks up a semiconductor die attached to an upper surface of a wafer sheet, the pickup apparatus of a semiconductor die comprising:
a stage which comprises a suction surface sucking a lower surface of the wafer sheet and an opening provided in the suction surface;
a stage drive mechanism which drives the stage in an up-down direction; and
a moving element which is arranged in the opening of the stage and moves so that a tip of the moving element protrudes from the suction surface,
the pickup apparatus of a semiconductor die comprising:
a moving element drive mechanism which drives the moving element in the up-down direction;
a collet which picks up the semiconductor die;
a vacuum device which creates a vacuum inside the stage; and
a control part which adjusts operations of the stage drive mechanism, the moving element drive mechanism, the collet, and the vacuum device,
wherein the stage has a cylindrical shape, the suction surface is a spherical cap surface which is curved convexly upward, the opening of the stage is arranged at a center of the suction surface, and the suction surface is composed of an inner peripheral part around the opening and an outer peripheral part on an outer side of the inner peripheral part, comprises, in the inner peripheral part, an inner suction hole communicating with the vacuum device, and comprises, in the outer peripheral part, an outer suction hole communicating with the vacuum device,
the control part raises, by the stage drive mechanism, the stage until the lower surface of the wafer sheet is in contact with an outer peripheral end of the inner peripheral part of the stage to push up the wafer sheet,
after pushing up the wafer sheet, the control part creates, by the vacuum device, a vacuum at the inner suction hole to suck the wafer sheet to the inner peripheral part of the suction surface, and
after sucking the wafer sheet to the suction surface, the control part protrudes, by the moving element drive mechanism, the moving element from the suction surface to push up the semiconductor die to be picked up from under the wafer sheet, and picks up, by the collet, the semiconductor die from the wafer sheet.

2. (canceled)

3. (canceled)

4. (canceled)

5. The pickup apparatus of a semiconductor die according to claim 1, wherein
when pushing up the wafer sheet, the control part raises the stage until the lower surface of the wafer sheet is in contact with an outer peripheral end of the outer peripheral part of the stage, and
when sucking the wafer sheet, the control part creates, by the vacuum device, a vacuum at the inner suction hole and the outer suction hole to suck the wafer sheet to the inner peripheral part and the outer peripheral part of the suction surface.

6. The pickup apparatus of a semiconductor die according to claim 5, wherein
in a case of picking up the semiconductor die attached to the upper surface of a peripheral portion of the wafer sheet,
when pushing up the wafer sheet, the control part raises the stage until the lower surface of the wafer sheet is in contact with the outer peripheral end of the inner peripheral part of the stage, and
when sucking the wafer sheet, the control part creates, by the vacuum device, a vacuum at the inner suction hole to suck the wafer sheet to the inner peripheral part of the suction surface, and
in a case of picking up the semiconductor die attached to the upper surface of a central portion of the wafer sheet,
when pushing up the wafer sheet, the control part raises the stage until the lower surface of the wafer sheet is in contact with the outer peripheral end of the outer peripheral part of the stage, and
when sucking the wafer sheet, the control part creates, by the vacuum device, a vacuum at the inner suction hole and the outer suction hole to suck the wafer sheet to the inner peripheral part and the outer peripheral part of the suction surface.

7. The pickup apparatus of a semiconductor die according to claim 1, wherein
the moving element is composed of: a first push-up pin arranged at a center of the stage; and
a second push-up pin in a cylindrical shape arranged on an outer circumference of the first push-up pin,
the moving element drive mechanism drives the first push-up pin and the second push-up pin in the up-down direction, and
when picking up the semiconductor die,
after protruding, by the moving element drive mechanism, the second push-up pin from the suction surface, the control part protrudes the first push-up pin to a position higher than a tip of the second push-up pin.

8. A pickup method of a semiconductor die which picks up a semiconductor die attached to an upper surface of a wafer sheet, the pickup method of a semiconductor die comprising:
a preparation process of preparing a pickup apparatus comprising: a stage which comprises a suction surface sucking a lower surface of the wafer sheet and an opening provided in the suction surface; a moving element which is arranged in the opening of the stage and moves so that a tip of the moving element protrudes from the suction surface; and a collet which picks up the semiconductor die, wherein the stage has a cylindrical shape, the suction surface is a spherical cap surface which is curved convexly upward, the opening of the stage is arranged at a center of the suction surface, and the suction surface is composed of an inner peripheral part around the opening and an outer peripheral part on an outer side of the inner peripheral part, comprises an inner suction hole in the inner peripheral part, and comprises an outer suction hole in the outer peripheral part;
a push-up process of raising the stage to push up the wafer sheet until the lower surface of the wafer sheet is in contact with an outer peripheral end of the inner peripheral part of the stage;
a suction process of creating, after the push-up process, a vacuum at the inner suction hole to suck the wafer sheet to the inner peripheral part of the suction surface; and
a pickup process of protruding, after the suction process, the moving element from the suction surface to push up the semiconductor die to be picked up from under the wafer sheet, and picking up the semiconductor die by the collet.

9. (canceled)

10. (canceled)

11. (canceled)

12. The pickup method of a semiconductor die according to claim 8, wherein
in the push-up process, the stage is raised until the lower surface of the wafer sheet is in contact with an outer peripheral end of the outer peripheral part of the stage, and
in the suction process, a vacuum is created at the inner suction hole and the outer suction hole to suck the wafer sheet to the inner peripheral part and the outer peripheral part of the suction surface.

13. The pickup method of a semiconductor die according to claim 12, wherein
in a case of picking up the semiconductor die attached to the upper surface of a peripheral portion of the wafer sheet,
in the push-up process, the stage is raised until the lower surface of the wafer sheet is in contact with the outer peripheral end of the inner peripheral part of the stage, and
in the suction process, a vacuum is created at the inner suction hole to suck the wafer sheet to the inner peripheral part of the suction surface, and
in a case of picking up the semiconductor die attached to the upper surface of a central portion of the wafer sheet,
in the push-up process, the stage is raised until the lower surface of the wafer sheet is in contact with the outer peripheral end of the outer peripheral part of the stage, and
in the suction process, a vacuum is created at the inner suction hole and the outer suction hole to suck the wafer sheet to the inner peripheral part and the outer peripheral part of the suction surface.

14. The pickup method of a semiconductor die according to claim 8, wherein
in the pickup apparatus of a semiconductor die prepared in the preparation process, the moving element is composed of a first push-up pin arranged at a center of the stage and a second push-up pin in a cylindrical shape arranged on an outer circumference of the first push-up pin, and
in the pickup process, after the second push-up pin is protruded from the suction surface, the first push-up pin is protruded to a position higher than a tip of the second push-up pin, and the semiconductor die is picked up by the collet.

15. The pickup apparatus of a semiconductor die according to claim 5, wherein
when pushing up the wafer sheet, the control part raises the stage until the lower surface of the wafer sheet is in contact with a corner part between a side surface in a cylindrical shape of the stage and the suction surface.

16. The pickup apparatus of a semiconductor die according to claim 15, wherein
the corner part is composed of a curved surface connecting the side surface of the stage and the suction surface, and
when pushing up the wafer sheet, the control part raises the stage until a height of a ridge line between the side surface of the stage and the suction surface at the corner part is equal to or greater than a height of the lower surface of the wafer sheet at the side surface of the stage.

17. The pickup method of a semiconductor die according to claim 12, wherein
in the push-up process, the stage is raised until the lower surface of the wafer sheet is in contact with a corner part between a side surface in a cylindrical shape of the stage and the suction surface.

18. The pickup method of a semiconductor die according to claim 17, wherein
in the pickup apparatus of a semiconductor die prepared in the preparation process, the corner part is composed of a curved surface connecting the side surface of the stage and the suction surface, and
in the push-up process, the stage is raised until a height of a ridge line between the side surface of the stage and the suction surface at the corner part is equal to or greater than a height of the lower surface of the wafer sheet at the side surface of the stage.
